(19) United States
(12) Patent Application Publication
(10) Pub. No.: US 2024/0304688 A1
(43) Pub. Date: Sep. 12, 2024

(54) SEMICONDUCTOR DEVICE HAVING CONTACT PLUG CONNECTED TO DIFFUSION REGION

(71) Applicant: MICRON TECHNOLOGY, INC., BOISE, ID (US)

(72) Inventors: MOEKO KAWANA, Hiroshima (JP); YOSHIKAZU MORIWAKI, Hiroshima (JP)

(73) Assignee: MICRON TECHNOLOGY, INC., Boise, ID (US)

(21) Appl. No.: 18/441,908

(22) Filed: Feb. 14, 2024

Related U.S. Application Data
(60) Provisional application No. 63/488,715, filed on Mar. 6, 2023.

(51) Int. Cl. H01L 29/417; H01L 29/40

(52) U.S. Cl. CPC H01L 29/41775; H01L 29/401

(57) ABSTRACT

An example apparatus includes a semiconductor substrate having first and second diffusion regions and a channel region arranged between the first and second diffusion regions; a gate electrode covering the channel region with a gate insulating film interposed therebetween; and first and second contact plugs connected to the first and second diffusion regions, respectively. Each of the first and second contact plugs includes an upper section and a lower section arranged between the upper section and an associated one of the first and second diffusion regions. The lower section has a smaller diameter than the upper section at a boundary cross-section between the lower and upper sections.

This application claims priority to U.S. Provisional Application No. 63/488,715, filed Mar. 6, 2023. The aforementioned application is incorporated herein by reference, in its entirety, for any purpose.

### BACKGROUND

Source and drain of a MOS transistor are connected to contact plugs penetrating through an interlayer insulating film. In order to reduce the resistance of the contact plug, it is necessary to increase the diameter thereof. However, when the diameter of the contact plug is increased, the distance from a gate electrode becomes smaller, which results in increase in parasitic capacitance.

### BRIEF DESCRIPTION OF THE DRAWINGS

FIG. 1 is a schematic cross-sectional view for explaining a configuration of a main part of a semiconductor device according to a first embodiment;

FIG. 2A is a schematic plan view at the height position shown with a broken line L1 in FIG. 1;

FIG. 2B is a schematic plan view at the height position shown with a broken line L2 in FIG. 1;

FIG. 3A is a schematic plan view for explaining a configuration of a contact plug;

FIG. 3B is a schematic cross-sectional view taken along a line A-A in FIG. 3A;

FIGS. 4A to 4H are diagrams of a manufacturing process of the contact plug; and

FIG. 5 is a schematic cross-sectional view for explaining a configuration of a main part of a semiconductor device according to a second embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

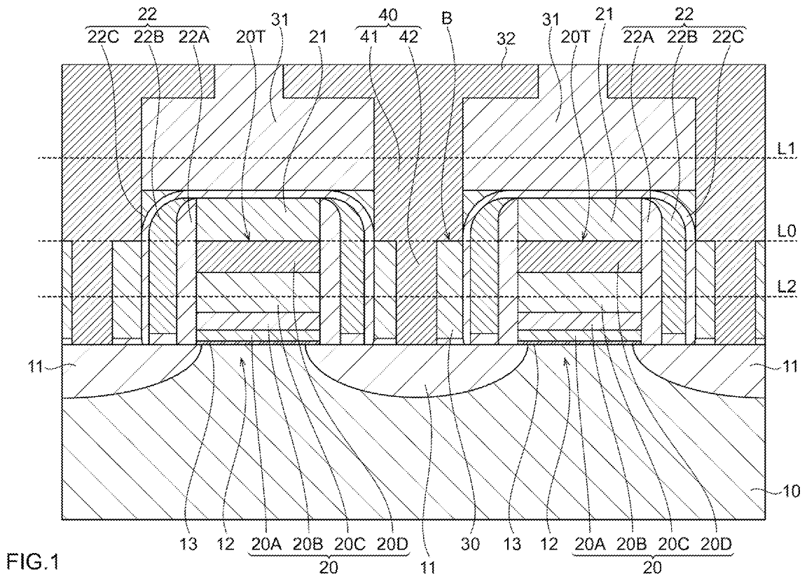

FIG. 1 is a schematic cross-sectional view for explaining a configuration of a main part of a semiconductor device according to a first embodiment. The semiconductor device shown in FIG. 1 includes a semiconductor substrate 10 made of, for example, silicon, a plurality of diffusion regions 11 formed in the semiconductor substrate 10 and serving as source/drain regions, and a channel region 12 arranged between the diffusion regions 11. The channel region 12 is covered with a gate electrode 20 via a gate insulating film 13. A pair of the diffusion regions 11, the channel region 12 arranged between them, and the gate electrode 20 covering the channel region 12 via the gate insulating film 13 constitute a MOS transistor. The gate electrode 20 may have a configuration in which a High-k film 20A, a metal film 20B, a polysilicon film 20C, and a tungsten film 20D are stacked on the gate insulating film 13 in this order. A top surface 20T of the gate electrode 20 is covered with a gate cap insulating film 21 made of, for example, silicon nitride. Side surfaces of the gate electrode 20 are covered with side wall insulating films 22. The side wall insulating film 22 may be a stacked film of a silicon nitride film 22A, a silicon oxide film 22B, and a silicon nitride film 22C. The MOS transistor having this configuration is covered with interlayer insulating films 30 and 31. The interlayer insulating film 30 is made of, for example, silicon oxide, and the interlayer insulating film 31 is made of, for example, silicon nitride.

A wiring pattern 32 provided on the interlayer insulating films 30 and 31 is connected to the diffusion regions 11 via contact plugs 40 penetrating through the interlayer insulating films 30 and 31. The contact plugs 40 each have an upper section 41 and a lower section 42. In the example shown in FIG. 1, the height position of a boundary B between the upper section 41 and the lower section 42 is coincident with the height position of the top surface 20T of the gate electrode 20 as shown with a broken line L0. The height position of the boundary B between the upper section 41 and the lower section 42 may be higher than the height position of the top surface 20T of the gate electrode 20.

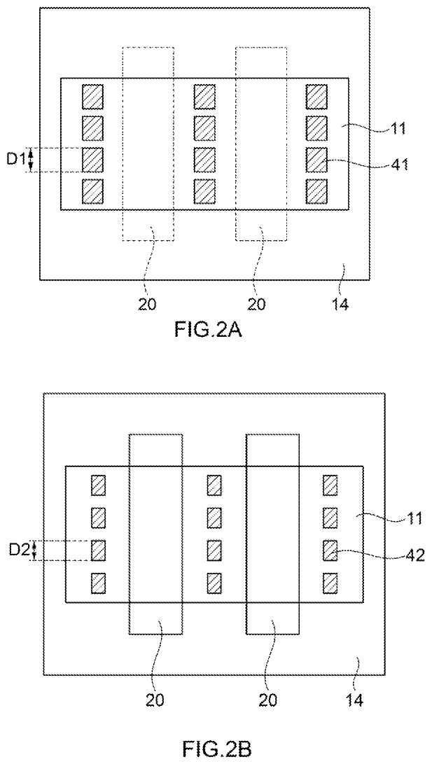

FIG. 2A is a schematic plan view at the height position shown with a broken line L1 in FIG. 1. FIG. 2B is a schematic plan view at the height position shown with a broken line L2 in FIG. 1. As shown in FIGS. 2A and 2B, the diffusion region 11 is surrounded by an STI region 14 made of silicon oxide. A plurality of the contact plugs 40 are assigned to each diffusion region 11. In the example shown in FIGS. 2A and 2B, four contact plugs 40 are assigned to each diffusion region 11. A diameter D2 of the lower section 42 of each contact plug 40 is smaller than a diameter D1 of the upper section 41 of the contact plug 40. Accordingly, as shown in FIG. 1, the distance in the horizontal direction from the gate electrode 20 increases in the lower section 42 as compared with a case where the contact plug 40 entirely has the diameter D1, so that parasitic capacitance generated between the gate electrode 20 and the contact plug 40 is reduced. Further, as compared with a case where the contact plug 40 entirely has the diameter D2, a resistance value of the contact plug 40 is reduced. The planar shapes of the upper section 41 and the lower section 42 of the contact plug 40 are not specifically limited, and may be substantially square or substantially rectangular or be substantially circular or substantially elliptical.

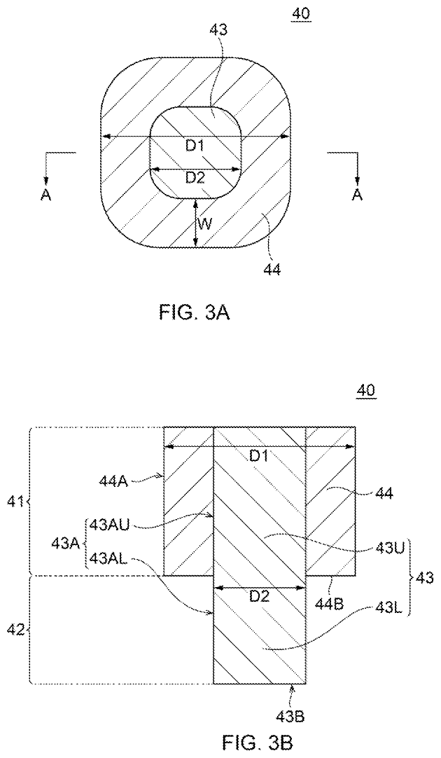

FIG. 3A is a schematic plan view for explaining a configuration of the contact plug 40. FIG. 3B is a schematic cross-sectional view taken along a line A-A in FIG. 3A. As shown in FIGS. 3A and 3B, the contact plug 40 is constituted by a first part 43 and a second part 44. The first part 43 and the second part 44 may be made of the same conductive material, such as tungsten, as each other or conductive materials different from each other. The first part 43 has an outer side surface 43A and a bottom surface 43B. The bottom surface 43B of the first part 43 is in contact with the diffusion region 11. The first part 43 has an upper region 43U and a lower region 43L. In the outer side surface 43A, an outer side surface 43AU of the upper region 43U is surrounded by the second part 44, whereas an outer side surface 43AL of the lower region 43L is not surrounded by the second part 44 but is in contact with the interlayer insulating film 30 shown in FIG. 1. The second part 44 has an outer side surface 44A and a bottom surface 44B. The bottom surface 44B of the second part 44 is located at the boundary B between the upper section 41 and the lower section 42 and faces a surface of the semiconductor substrate 10. The bottom surface 44B of the second part 44 and the surface of the semiconductor substrate 10 may be substantially parallel to each other. As shown in FIG. 1, a part of the outer side surface 44A of the second part 44 is in contact with the interlayer insulating film 30, and another part is in contact with the interlayer insulating film 31. The bottom surface 44B of the second part 44 has a ring shape and is in contact with the interlayer insulating film 30.

The upper region 43U of the first part 43 and the second part 44 constitute the upper section 41 of the contact plug 40, and the lower region 43L of the first part 43 constitutes the lower section 42 of the contact plug 40. The diameter of the upper section 41 is D1, and the diameter of the lower section 42 is D2. A difference between the diameter D1 of the upper section 41 and the diameter D2 of the lower section 42 is 2×W. The width in the radial direction of the bottom surface 44B of the second part 44 having a ring shape is W and is substantially constant over the entire circumference. This fact means that, in plan view, the first part 43 is not offset with respect to the second part 44 and is located approximately at the center. In other words, the thickness in the horizontal direction of the second part 44, which is tubular, is substantially constant.

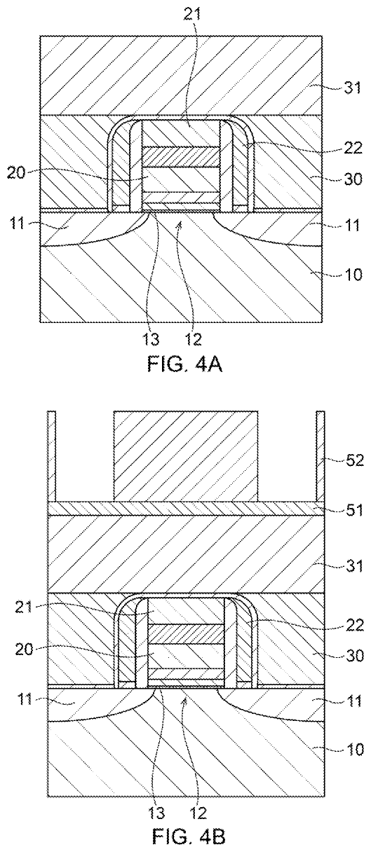

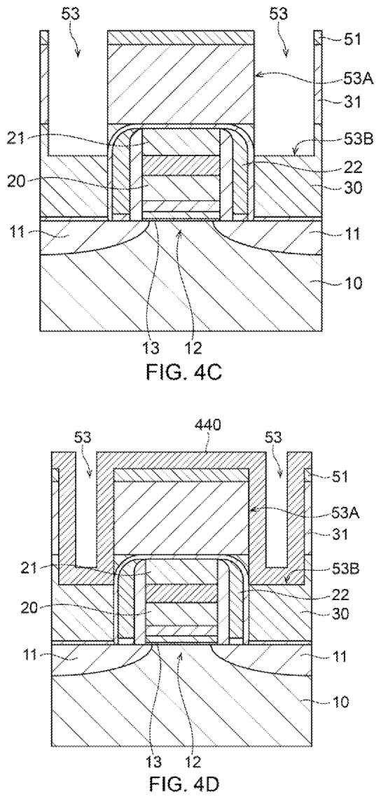

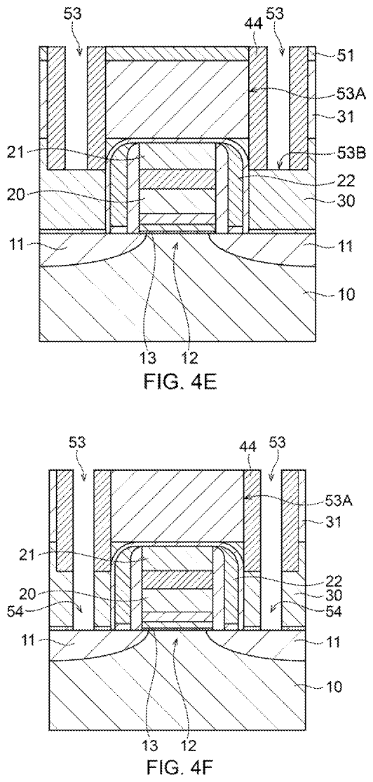

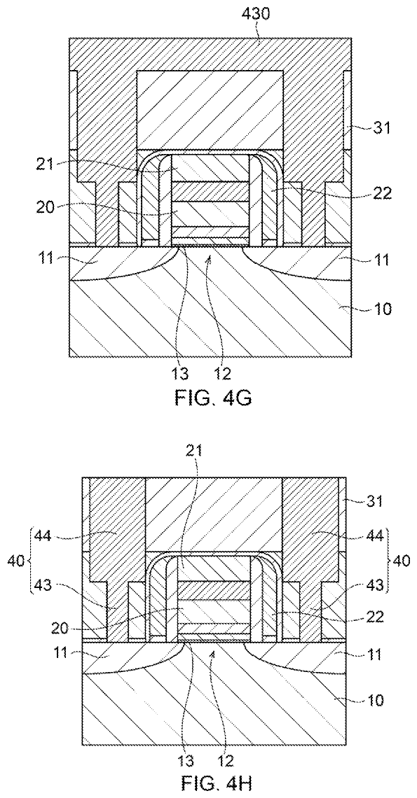

Next, a manufacturing process of the contact plug 40 is described with reference to FIGS. 4A to 4H. First, the gate electrode 20, the gate cap insulating film 21, and the side wall insulating film 22 are formed on the semiconductor substrate 10, and the interlayer insulating films 30 and 31 are then formed to embed the gate electrode 20, the gate cap insulating film 21, and the side wall insulating film 22 (FIG. 4A). Subsequently, a hard mask 51 made of, for example, polysilicon is formed on the interlayer insulating film 31, and thereafter a photoresist 52 is formed on a surface of the hard mask 51 and is patterned by photolithography (FIG. 4B). The hard mask 51 is then patterned with the photoresist 52 used as a mask, and thereafter a trench 53 is formed in the interlayer insulating films 31 and 30 with the hard mask 51 used as a mask (FIG. 4C). The diameter of the trench 53 is D1 shown in FIG. 3A. A bottom surface 53B of the trench 53 corresponds to the height position of the boundary B between the upper section 41 and the lower section 42 shown in FIG. 1. Therefore, the depth of the trench 53 is set in such a manner that the bottom surface 53B is at the height position the same as or higher than the height position of the top surface 20T of the gate electrode 20.

Subsequently, a conductive material 440, such as tungsten and a barrier metal, is deposited on the entire surface (FIG. 4D). An inner side wall 53A and the bottom surface 53B of the trench 53 are thus covered with the conductive material 440. In this deposition, the thickness of the conductive material 440 is controlled in such a manner that the trench 53 is not completely filled with the conductive material 440. The thickness of the conductive material 440 corresponds to the width W shown in FIG. 3A. Accordingly, a space formed by the trench 53 is reduced by deposition of the conductive material 440, so that the diameter of the space is changed from D1 to D2. Next, the conductive material 440 is etched back, whereby the bottom surface 53B of the trench 53 is exposed again with the conductive material 440 covering the inner side wall 53A of the trench 53 left (FIG. 4E). Consequently, the diameter of the exposed bottom surface 53B of the trench 53 corresponds to the diameter D2 shown in FIG. 3A. The conductive material 440 left on the inner side wall 53A of the trench 53 constitutes the second part 44 of the contact plug 40.

Subsequently, a trench 54 is formed in the interlayer insulating film 30 with the second part 44 of the contact plug 40 used as a mask (FIG. 4F). The trench 54 reaches the diffusion region 11, whereby the diffusion region 11 is exposed at the bottom of the trench 54. The diameter of the trench 54 is D2 shown in FIG. 3A. Next, a conductive material 430, such as tungsten, is deposited on the entire surface to embed the trenches 53 and 54 (FIG. 4G). An unnecessary portion of the conductive material 430 formed on the top surface of the interlayer insulating film 31 is then removed by CMP (FIG. 4H). Consequently, the conductive material 430 left in the trenches 53 and 54 constitutes the first part 43 of the contact plug 40. Thereafter, the wiring pattern 32 and the like are formed on the interlayer insulating film 31, so that the configuration shown in FIG. 1 can be obtained.

As described above, in the present embodiment, the trench 53 is formed in the interlayer insulating films 31 and 30, and thereafter the diameter of the trench 53 is reduced by covering the inner side wall 53A of the trench 53 by the conductive material 440. Thereafter, the other trench 54 having a smaller diameter than the trench 53 is formed in the interlayer insulating film 30. Accordingly, the contact plug 40 can be formed in which the diameter D1 of the upper section 41 is larger and the diameter D2 of the lower section 42 is smaller.

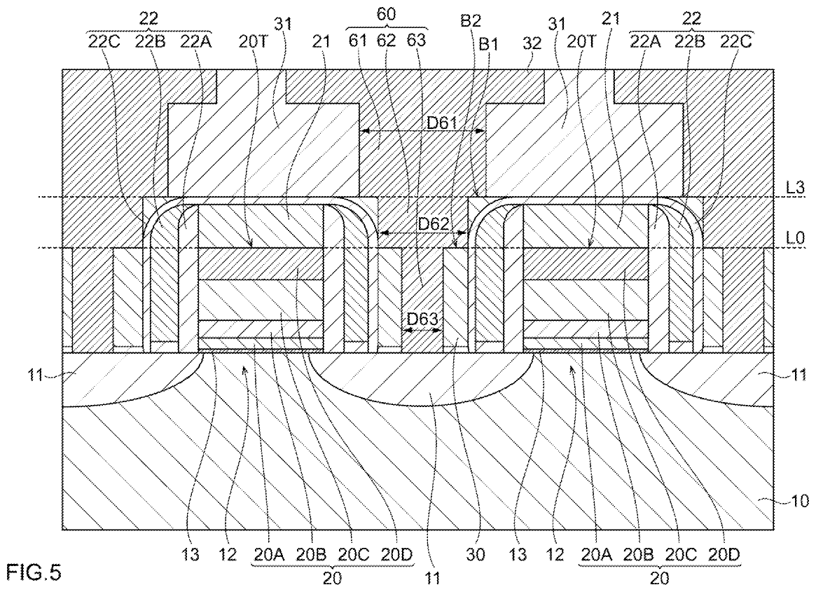

FIG. 5 is a schematic cross-sectional view for explaining a configuration of a main part of a semiconductor device according to a second embodiment. In the semiconductor device shown in FIG. 5, a contact plug 60 has an upper section 61, a middle section 62, and a lower section 63. A diameter D61 of the upper section 61 is larger than a diameter D62 of the middle section 62, and a diameter D63 of the lower section 63 is smaller than the diameter D62 of the middle section 62. In the example shown in FIG. 5, the height position of a boundary B2 between the lower section 63 and the middle section 62 is coincident with the height position of the top surface 20T of the gate electrode 20, as shown with the broken line L0. Further, the height position of a boundary B1 between the upper section 61 and the middle section 62 is coincident with the height position of the interlayer insulating film 30, as shown with a broken line L3. This configuration is obtained by using the interlayer insulating film 30 as an etching stopper when a trench for forming the upper section 61 is formed in the interlayer insulating film 31.

As exemplified by the semiconductor device according to the second embodiment shown in FIG. 5, the diameter of the contact plug 60 may change in three or more steps in the depth direction. Such diameter design can further reduce a resistance value of the contact plug 60 while suppressing increase in parasitic capacitance of the contact plug 60.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a semiconductor substrate having first and second diffusion regions and a channel region arranged between the first and second diffusion regions;
a gate electrode covering the channel region with a gate insulating film interposed therebetween; and
first and second contact plugs connected to the first and second diffusion regions, respectively,
wherein each of the first and second contact plugs including:
a first part having an upper section and a lower section; and
a second part surrounding a first outer side surface of the upper section of the first part.

2. The apparatus of claim 1, wherein the second part does not surround a second outer side surface of the lower section of the first part.

3. The apparatus of claim 2, wherein the second part has a third outer side surface and a bottom surface substantially perpendicular to the third outer side surface.

4. The apparatus of claim 3, further comprising an interlayer insulating film surrounding the second outer side surface of the lower section of the first part,
wherein the bottom surface of the second part contacts with the interlayer insulating film.

5. The apparatus of claim 3, wherein a height position of the bottom surface of the second part is equal to or higher than a top surface of the gate electrode.

6. The apparatus of claim 1, wherein the first and second parts are made of the same conductive material as each other.

7. The apparatus of claim 1, wherein the first and second parts are made of different conductive material from each other.

8. An apparatus comprising:
a semiconductor substrate having first and second diffusion regions and a channel region arranged between the first and second diffusion regions;
a gate electrode covering the channel region with a gate insulating film interposed therebetween; and
first and second contact plugs connected to the first and second diffusion regions, respectively,
wherein each of the first and second contact plugs including an upper section and a lower section arranged between the upper section and an associated one of the first and second diffusion regions,
wherein the lower section has a smaller diameter than the upper section at a boundary cross-section between the lower and upper sections.

9. The apparatus of claim 8,
wherein the upper section has a first outer side surface and a bottom surface, and
wherein the bottom surface of the upper section defines the boundary cross-section.

10. The apparatus of claim 9, wherein the bottom surface of the upper section faces the semiconductor substrate.

11. The apparatus of claim 10, wherein the bottom surface of the upper section is substantially parallel with the semiconductor substrate.

12. The apparatus of claim 9, wherein the bottom surface of the upper section is ring-shaped.

13. The apparatus of claim 12, wherein a width of the bottom surface being ring-shaped in a radial direction is substantially constant.

14. The apparatus of claim 12, further comprising an interlayer insulating film surrounding a second outer side surface of the lower section,
wherein the bottom surface of the upper section contacts with the interlayer insulating film.

15. The apparatus of claim 8, wherein a height position of the boundary cross-section is equal to or higher than a top surface of the gate electrode.

16. The apparatus of claim 9,
wherein each of the first and second contact plugs includes first and second parts,
wherein the lower section and a part of the upper section constitute the first part, and
wherein another part of the upper section constitutes the second part.

17. The apparatus of claim 16,
wherein the first part has the first outer side surface and a third outer side surface, and
wherein the second part surrounds the third outer side surface of the first part without surrounding the first outer side surface of the first part.

18. The apparatus of claim 16, wherein the first and second parts are made of the same conductive material as each other.

19. The apparatus of claim 16, wherein the first and second parts are made of different conductive material from each other.

20. A method comprising:
covering a transistor including a diffusion region with an interlayer insulating;
forming a first trench in the interlayer insulating film so as to remain a part of the interlayer insulating film on a bottom of the first trench;
forming a first conductive film on an inner wall of the first trench such that a space of the first trench is reduced;
forming a second trench in the interlayer insulating film by using the first conductive film as a mask so as to expose a part of the diffusion region; and
filling first and second trenches with a second conductive film.

21. The method of claim 20,
wherein the transistor further includes a gate electrode, and
wherein a height position of the bottom of the first trench is equal to or higher than a top surface of the gate electrode.
